(19) United States
(12) Patent Application Publication
(10) Pub. No.: US 2009/0317937 A1
(43) Pub. Date: Dec. 24, 2009

(54) Maskless Doping Technique for Solar Cells

(76) Inventors: Atul Gupta, Beverly, MA (US); Nicholas Bateman, Burlington, MA (US); Paul Murphy, Reading, MA (US); Anthony Renau, West Newbury, MA (US); Charles Carlson, Cedar Park, TX (US)

Correspondence Address: Nields, Lemack & Frame, LLC, 176 E. MAIN STREET, SUITE 5, WESTBOROUGH, MA, 01581, US

(21) Appl. No.: 12/200,117

(22) Filed: Aug. 28, 2008

Related U.S. Application Data
(60) Provisional application No. 61/074,278, filed on Jun. 20, 2008.

(51) Int. Cl. H01L 21/00

(52) U.S. Cl. 438/80; 257/E21.001

(57) ABSTRACT

A improved, lower cost method of producing solar cells utilizing selective emitter design is disclosed. The contact regions are created on the substrate without the use of lithography or masks. The method utilizes ion implantation technology, and the relatively low accuracy requirements of the contact regions to reduce the process steps needed to produce a solar cell. In some embodiments, the current of the ion beam is selectively modified to create the highly doped contact regions. In other embodiments, the ion beam is focused, either through the use of an aperture or via adjustments to the beam line components to create the necessary doping profile. In still other embodiments, the wafer scan rate is modified to create the desired ion implantation pattern.

This application claims priority of U.S. Provisional Patent Application Ser. No. 61/074,278, filed Jun. 20, 2008, the disclosure of which is incorporated herein by reference.

### BACKGROUND OF THE INVENTION

Solar cells are typically manufactured using the same processes used for other semiconductor devices, often using silicon as the substrate material. A semiconductor solar cell is a simple device having an in-built electric field that separates the charge carriers generated through the absorption of photons in the semiconductor material. This electric-field is typically created through the formation of a p-n junction (diode) which is created by differential doping of the semiconductor material. Doping a part of the semiconductor substrate (e.g. surface region) with impurities of opposite polarity forms a p-n junction that may be used as a photovoltaic device converting light into electricity.

FIG. 1 shows a cross section of a representative substrate 100, comprising a solar cell. Photons 10 enter the solar cell 100 through the top surface 105, as signified by the arrows. These photons pass through an anti-reflective coating 110, designed to maximize the number of photons that penetrate the substrate 100 and minimize those that are reflected away from the substrate.

Internally, the substrate 100 is formed so as to have a p-n junction 120. This junction is shown as being substantially parallel to the top surface 105 of the substrate 100 although there are other implementations where the junction may not be parallel to the surface. The solar cell is fabricated such that the photons enter the substrate through the n-doped region, also known as the emitter 130. The photons with sufficient energy (above the bandgap of the semiconductor) are able to promote an electron within the semiconductor material's valence band to the conduction band. Associated with this free electron is a corresponding positively charged hole in the valence band. In order to generate a photocurrent that can drive an external load, these electron hole (e-h) pairs need to be separated. This is done through the built-in electric field at the p-n junction. Thus any e-h pairs that are generated in the depletion region of the p-n junction get separated, as are any other minority carriers that diffuse to the depletion region of the device. Since a majority of the incident photons are absorbed in near surface regions of the device, the minority carriers generated in the emitter need to diffuse across the depth of the emitter to reach the depletion region and get swept across to the other side. Thus to maximize the collection of photo-generated current and minimize the chances of carrier recombination in the emitter, it is preferable to have the emitter region 130 be very shallow.

Some photons pass through the emitter region 130 and enter the base 140. These photons can then excite electrons within the base 140, which are free to move into the emitter region 130, while the associated holes remain in the base 140. As a result of the charge separation caused by the presence of this p-n junction, the extra carriers (electrons and holes) generated by the photons can then be used to drive an external load to complete the circuit.

By externally connecting the emitter region 130 to the base 140 through an external load, it is possible to conduct current and therefore provide power. To achieve this, contacts 150, typically metallic, are placed on the outer surface of the emitter region and the base. Since the base does not receive the photons directly, typically its contact 150b is placed along the entire outer surface. In contrast, the outer surface of the emitter region receives photons and therefore cannot be completely covered with contacts. However, if the electrons have to travel great distances to the contact, the series resistance of the cell increases, which lowers the power output. In an attempt to balance these two considerations; the distance that the free electrons must travel to the contact, and the amount of exposed emitter surface 160; most applications use contacts 150a that are in the form of fingers. FIG. 2 shows a top view of the solar cell of FIG. 1. The contacts are typically formed so as to be relatively thin, while extending the width of the solar cell. In this way, free electrons need not travel great distances, but much of the outer surface of the emitter is exposed to the photons. Typical contact fingers 150a on the front side of the wafer are 0.3 mm with an accuracy of ±0.1 mm. These fingers 150a are typically spaced between 1-5 mm apart from one another. While these dimensions are typical, other dimensions are possible and contemplated herein.

A further enhancement to solar cells is the addition of heavily doped substrate contact regions. FIG. 3 shows a cross section of this enhanced solar cell. The cell is as described above in connection with FIG. 1, but includes heavily n-doped contact regions 170. These heavily doped contact regions 170 correspond to the areas where the metallic fingers 150a will be affixed to the substrate 100. The introduction of these heavily doped contact regions 170 allows much better contact between the substrate 100 and the metallic fingers 150a and significantly lowers the series resistance of the cell. This pattern of including heavily doped regions on the surface of the substrate is commonly referred to as selective emitter design.

A selective emitter design for a solar cell also has the advantage of higher efficiency cells due to reduced minority carrier losses through recombination due to lower dopant/impurity dose in the exposed regions of the emitter layer. The higher doping under the contact regions provides a field that repels the minority carriers generated in the emitter and pushes them towards the p-n junction.

This design can be extended by having narrow highly doped lines between the metallization lines. Such lines could be orthogonal to the metallization lines. These highly doped, low resistance lines allow charge to flow across the emitter to the contacts, and reduce the series resistance of the emitter.

Such structures are typically made using traditional lithography (on hard masks) and thermal diffusion. An alternative is to use implantation in conjunction with a traditional lithographic mask, which can then be removed easily before dopant activation. Yet another alternative is to use a stencil mask in the implanter to define the highly doped areas for the contacts. All of these techniques utilize a fixed masking layer (either directly on the substrate or in the beamline).

All of these alternatives have significant drawbacks. For example, the processes enumerated above all contain multiple process steps. This causes the cost of the manufacturing process to be prohibitive. These options also suffer from the limitations associated with the special handling of solar wafers, such as aligning the mask with the substrate and the cross contamination with materials that are dispersed from the mask during ion implantation.

Therefore, these exists a need to produce solar cells having selective emitters for increased efficiency, while producing these cells at lower cost. A simpler, more cost effective method of manufacturing solar cells is required. While initially applicable to solar cells, the techniques described herein are applicable to other doping applications.

### SUMMARY OF THE INVENTION

A improved, lower cost method of producing solar cells utilizing selective emitter design is disclosed. The contact regions are created on the substrate without the use of lithography or masks. The method utilizes ion implantation technology, and the relatively low accuracy requirements of the contact regions to reduce the process steps needed to produce a solar cell. In some embodiments, the current of the ion beam is selectively modified to create the highly doped contact regions. In other embodiments, the ion beam is focused, either through the use of an aperture or via adjustments to the beam line components to create the necessary doping profile. In still other embodiments, the wafer scan rate is modified to create the desired ion implantation pattern. These techniques can also be used in other ion implanter applications.

### BRIEF DESCRIPTION OF THE FIGURES

FIG. 1 shows a cross section of a solar cell of the prior art;

FIG. 2 shows a top view of the solar cell of FIG. 1;

FIG. 3 shows a cross section of a solar cell using selective emitter design;

FIG. 4 shows a top view of the solar cell of FIG. 3;

FIG. 5 shows a coordinate system used with the present disclosure;

FIG. 6 shows a traditional ion implantation system;

FIG. 7 shows a graph of substrate holder speed as a function of substrate position;

FIG. 8 shows a graph of scanner frequency as a function of substrate position;

FIG. 9 shows a pulsed extraction electrode power supply for use with the ion implanter of FIG. 6;

FIG. 10a shows a set of plates in the open position for use with the ion implanter of FIG. 6;

FIG. 10b shows a set of plates in the closed position for use with the ion implanter of FIG. 6;

FIG. 11a shows an aperture in the open position for use with the ion implanter of FIG. 6;

FIG. 11b shows an aperture in the closed position for use with the ion implanter of FIG. 6;

FIG. 12a shows a representative scanning waveform used to create non-uniform dosing;

FIG. 12b shows a representative substrate creating using the scanning waveform of FIG. 12a; and

FIG. 13 shows an embodiment wherein the scanning waveform is used to adjust a focusing element.

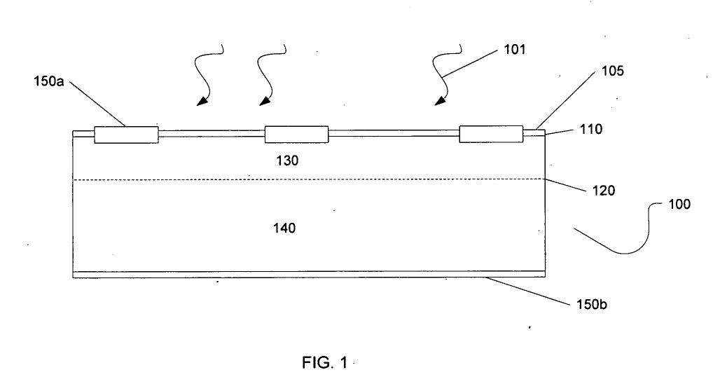

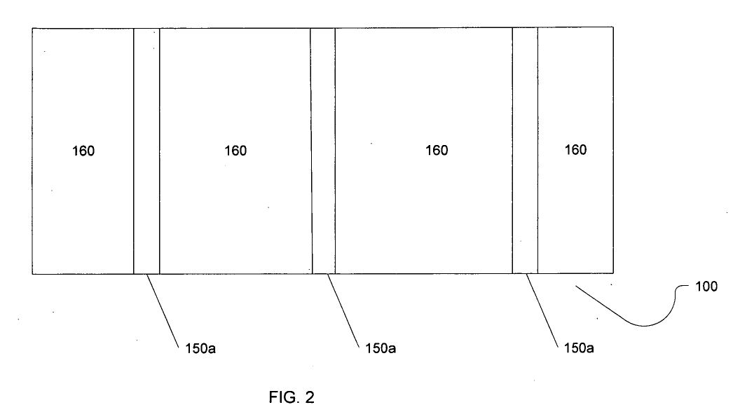

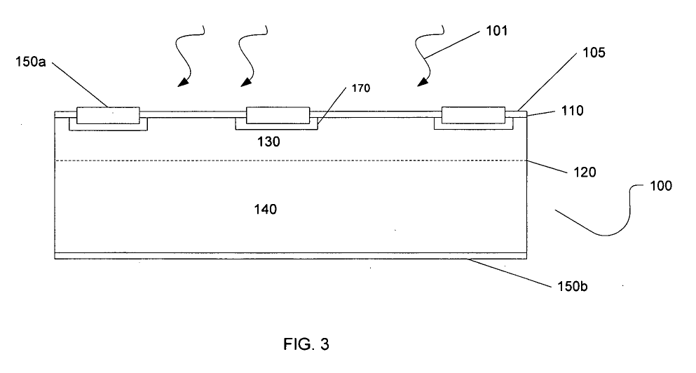

### DETAILED DESCRIPTION OF THE INVENTION

As described above, solar cells utilizing selective emitter design are most advantageous, however the manufacturing process needed to create such cells can be cost prohibitive. By understanding the relative accuracy and requirements of the solar cell, it is possible to manufacture solar cells having a selective emitter design without the costly lithography and masking process steps.

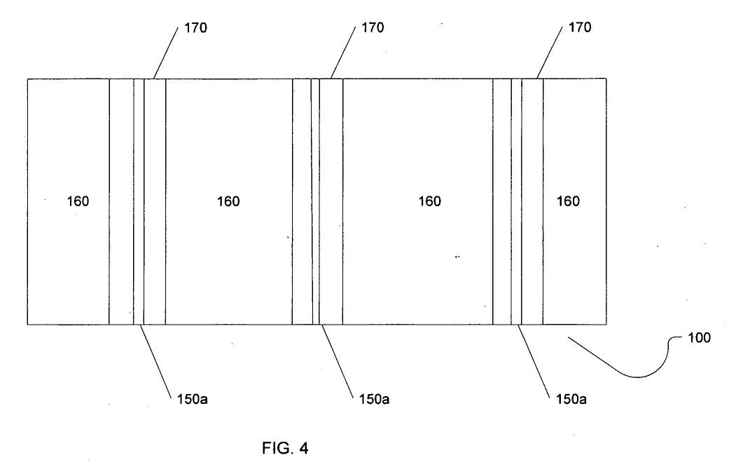

FIG. 4 shows a top view of the solar cell manufactured using the methods of the present disclosure. The solar cell is formed on a semiconductor substrate 100. The substrate can be any convenient size, including but not limited to circular, rectangular, or square. Although not a requirement, it is preferable that the width of the substrate 100 be less than the width of the ion beam used to implant ions in the substrate 100. However, no such limitation exists with respect to the orthogonal direction of the substrate. In other words, a substrate 100 can be arbitrarily long, and can be in the shape of roll of solar cell material. Typically, the substrates for solar cells are very thin, often on the order of 300 microns thick or less.

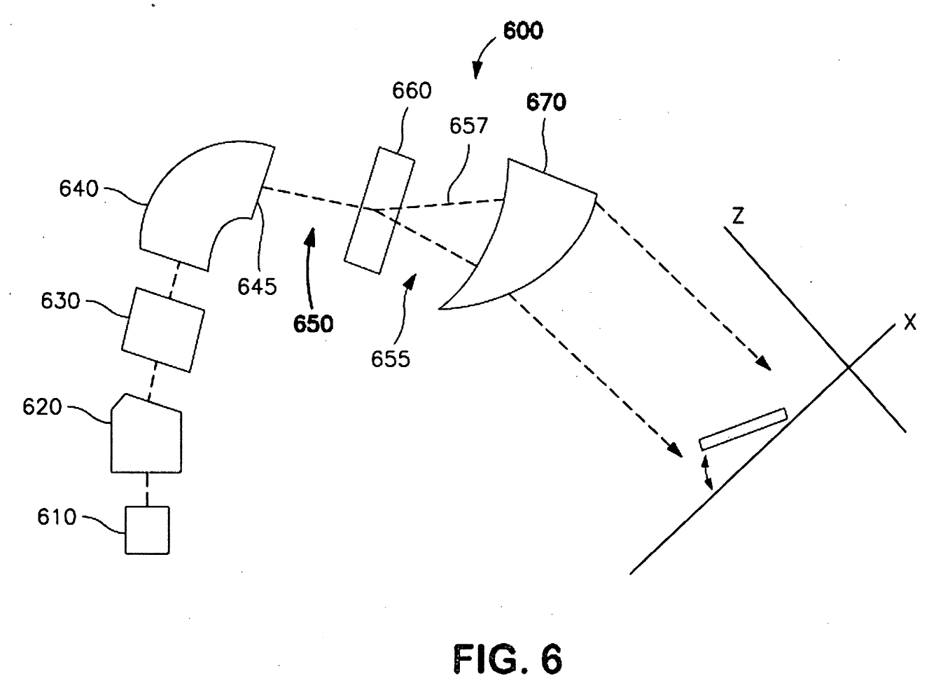

As described above, the solar cell has an n-doped emitter region and a p-doped base. The substrate is typically p-doped and forms the base, while ion implantation is used to create the emitter region. A block diagram of a representative ion implanter 600 is shown in FIG. 6. An ion source 610 generates ions of a desired species, such as phosphorus or boron. A set of electrodes (not shown) is typically used to attract the ions from the ion source. By using an electrical potential of opposite polarity to the ions of interest, the electrodes draw the ions from the ion source, and the ions accelerate through the electrode. These attracted ions are then formed into a beam, which then passes through a source filter 620. The source filter is preferably located near the ion source. The ions within the beam are accelerated/decelerated in column 630 to the desired energy level. A mass analyzer magnet 640, having an aperture 645, is used to remove unwanted components from the ion beam, resulting in an ion beam 650 having the desired energy and mass characteristics passing through resolving aperture 645.

In certain embodiments, the ion beam 650 is a spot beam. In this scenario, the ion beam passes through a scanner 660, preferably an electrostatic scanner, which deflects the ion beam 650 to produce a scanned beam 655 wherein the individual beamlets 657 have trajectories which diverge from scan source 665. In certain embodiments, the scanner 660 comprises separated scan plates in communication with a scan generator. The scan generator creates a scan voltage waveform, such as a sine, sawtooth or triangle waveform having amplitude and frequency components, which is applied to the scan plates. In a preferred embodiment, the scanning waveform is typically very close to being a triangle wave (constant slope), so as to uniformly expose the scanned beam at every position of the substrate for nearly the same amount of time. Deviations from the triangle are used to make the beam uniform. The resultant electric field causes the ion beam to diverge as shown in FIG. 6.

An angle corrector 670 is adapted to deflect the divergent ion beamlets 657 into a set of beamlets having substantially parallel trajectories. Preferably, the angle corrector 670 comprises a magnet coil and magnetic pole pieces that are spaced apart to form a gap, through which the ion beamlets pass. The coil is energized so as to create a magnetic field within the gap, which deflects the ion beamlets in accordance with the strength and direction of the applied magnetic field. The magnetic field is adjusted by varying the current through the magnet coil. Alternatively, other structures, such as parallelizing lenses, can also be utilized to perform this function.

Following the angle corrector 670, the scanned beam is targeted toward the substrate, such as the solar cell to be processed. The scanned beam typically has a height (Y dimension) that is much smaller than its width (X dimension). This height is much smaller than the substrate, thus at any particular time, only a portion of the substrate is exposed to the ion beam. To expose the entire substrate to the ion beam, the substrate must be moved relative to the beam location.

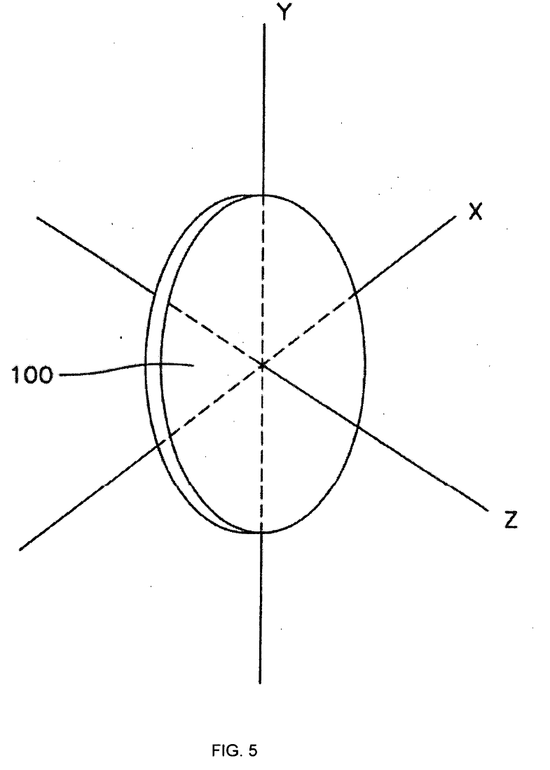

The solar cell is attached to a substrate holder. The substrate holder provides a plurality of degrees of movement. For example, the substrate holder can be moved in the direction orthogonal to the scanned beam. A sample coordinate system in shown in FIG. 5. Assume the beam is in the XZ plane. This beam can be a ribbon beam, or a scanned spot beam. The substrate holder can move in the Y direction. By doing so, the entire surface of the substrate 100 can be exposed to the ion beam, assuming that the substrate 100 has a smaller width than the ion beam (in the X dimension).

There are a number of methods that can be used to create the doping pattern shown in FIG. 4. Some of these methods require the wafer to be implanted in two separate process steps, while others can achieve the desired result in only one pass.

For clarity, the term “exposed emitter region” will be used to denote the lightly doped portions of the emitter region. The term “contact region” will be used to denote the heavily doped portions of the emitter region. The term “emitter region” refers to any n-doped portion of the substrate.

In several embodiments, the lightly doped exposed emitter region 160 is created by traditional implantation techniques. For example, a low current ion beam can be used to implant the entire surface of the substrate 100 at a uniform doping level.

In the case of a ribbon beam, the substrate 100 is positioned between the two ends of the beam, and the substrate holder moves the substrate 100 in the Y direction until the entire substrate has been exposed to the beam. The amount of doping that results from the implantation is proportional to the current of the ion beam, and the dwell time, which is the amount of time that a particular area is exposed to the ion beam. In other words, greater dwell time and/or higher current will result in heavier doping of the irradiated area.

Thus, by properly moderating the speed of the substrate scan, and/or the current of the ion beam, the substrate can be exposed to the required low dosage to create the exposed emitter region 160.

In the case of a scanned spot beam, the beam is normally scanned along the X direction. The substrate holder then moves the substrate in the Y direction. Using this combination of movements, the entire substrate is exposed. The same result can be obtained using a fixed spot beam and moving the substrate holder in both the X and Y directions, until the entire surface is exposed. These and other methods of implanting a substrate are known to those of ordinary skill in the art, and are all contemplated herein.

In all cases, the resulting ion beam has a width (in the X dimension) much greater than its height (in the Y dimension). Thus, if aspect ratio is defined as width/height, the resultant ion beam has an aspect ratio greater than 2, preferably greater than 10.

Once the emitter region 130 has been uniformly doped, the highly doped contact regions 170 are implanted during a second implantation step. This can be accomplished in a number of ways.

In one embodiment, the movement of the substrate holder is modified so as to create longer dwell times at the regions corresponding to the contacts for the metallic fingers. In other words, the substrate holder is moved more quickly in the Y direction over those portions of the substrate that are not to be further implanted (i.e. the exposed emitter regions 160). Once the ion beam is positioned over a region that is to be heavily doped (i.e. the contact region 170), the speed of the substrate holder in the Y direction slows. This slower speed is maintained while the ion beam is over the contact region. Once that region has been fully exposed, the translational speed of the substrate holder increases so as to quickly pass over the subsequent lightly doped exposed emitter region 160. This process is repeated until the entire substrate has been implanted.

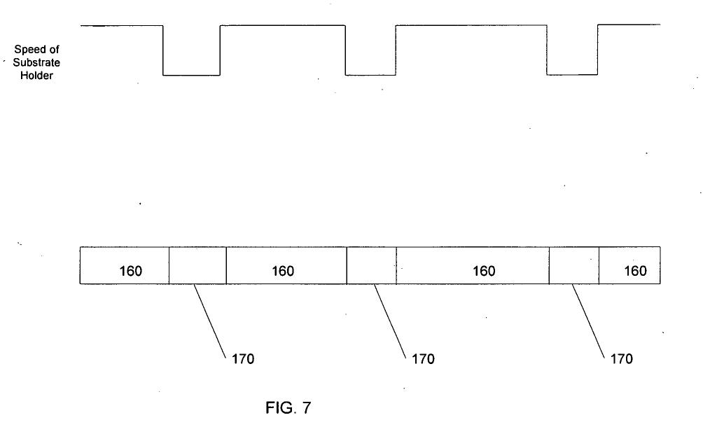

FIG. 7 shows a graph slowing the relative speed of the substrate holder in the Y direction, as a function of the position of the substrate. Note that when the exposed emitter region 160 is exposed to the ion beam, the speed is increased. When the contact region 170 is exposed to the ion beam, the speed is slowed to increase the doping dose. In some embodiments, the speed may be varied continuously between 2 levels to have continuously graded dopant profiles with regions of high doping (for contacts) with lightly doped regions in between. Such a velocity profile could be sinusoidal or triangular.

In the case of a spot beam, a similar technique can be used to move the substrate holder at a variable speed in the Y direction, based on the position on the substrate. If the substrate holder also moves in the X direction to scan across the wafer, the holder can vary the speed in the X direction to achieve the same results described above. In other words, the substrate holder moves quickly in the X direction while exposing lightly doped exposed emitter regions of the substrate, but slows when exposing the contact regions. Alternatively, the speeds of the substrate holder can be varied in both the X and Y directions if desired.

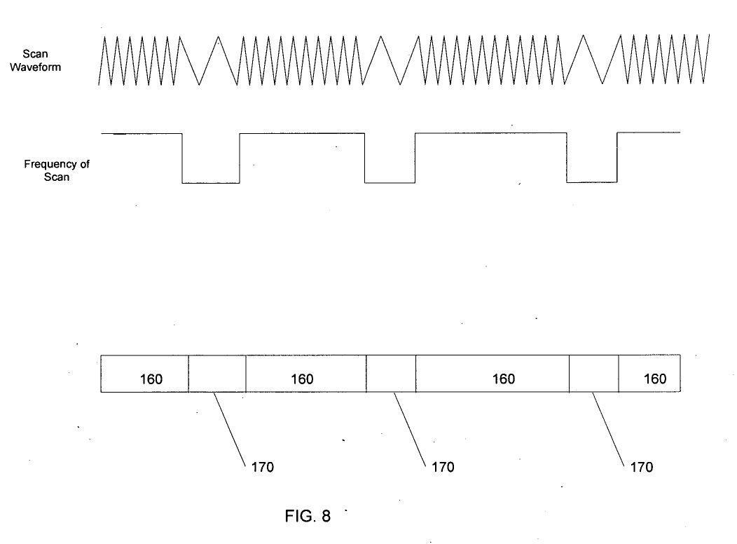

Alternatively, the scanner 660 can be controlled to create a similar result. Assume, in a scanned spot beam implementation, for example, that the substrate holder moves in the Y direction, and that the scanner 660 causes the spot beam to move in the X direction. By varying the frequency of the sawtooth wave used to control the scanner, the rate that the spot beam traverses the substrate can be modified. In one scenario, the frequency of the scanner control signal is increased as the ion beam passes over the exposed emitter region, and is slowed when the ion is exposed to the contact region. FIG. 8 shows a graph representing this embodiment. In this way, the dwell time of the exposed emitter region is less than that of the contact region. In another scenario, the waveform of the scanner control signal is modified so that the spot beam is positioned so as not to strike the substrate when passing through the exposed emitter region, and only scans when in the contact region. Combining the modification to the scanner input waveform with an alteration to the speed of the substrate holder in the Y direction can also be performed.

It should be noted that the embodiments presented above, i.e. modifications to the speed of the substrate holder in the X and/or Y directions, and modifications to the scanner frequency, can be employed in either two pass or single pass mode.

In single pass mode, the speed of the substrate holder in the Y direction is such that the required low dosage of ions is implanted in the exposed emitter region. Obviously, in this mode, the beam must pass over the substrate at all locations; it is only the dwell time at the various locations that is modified.

In dual pass mode, the speed of the substrate holder in the Y direction can be increased significantly over the exposed emitter region 160, as this area has already been doped. Alternatively, in the case of a spot beam, the beam can be positioned so as not to hit the substrate in the exposed emitter region 160, and only be exposed to the substrate while in the contact region 170.

While the above methods are mostly concerned with varying the dwell time of the ion beam for various portions of the substrate to vary the doping doses, other methods can be used to create the desired implantation pattern.

One such technique to create the desired implantation pattern is to vary the ion beam current based on the region of the substrate. This can be accomplished in a number of ways.

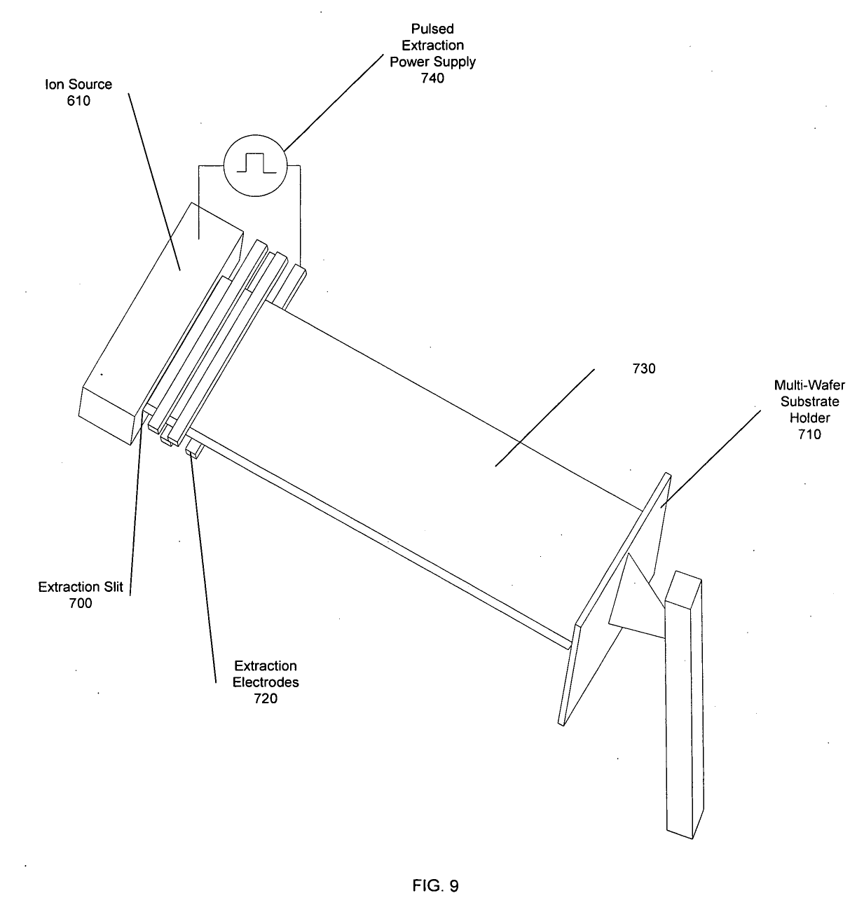

In one embodiment, the ion beam is adjusted by varying the voltage used at the extraction electrodes. FIG. 9 shows a simplified ion implantation system, with only the ion source 600 and the substrate holder 710 shown for clarity. The ion source 600 is used to generate the ion beam 730 to be implanted on the substrate 100. These ions are attracted through the extraction slit 700 of the ion source by one or more sets of extraction electrodes 720. The electrical potential of these electrodes 720 determines the resulting ion beam current. For example, if the electrical potential of the electrodes 720 is very similar to that of the chamber walls of the ion source 600, the flow of ions out of the ion source 600 will be minimal, as there is no attraction to the electrode. Conversely, if the electrical potential is dramatically different than the chamber walls of the ion source, the ions will be strongly attracted to the electrodes 720. This will result in an ion beam 730 of much higher current. By varying the electrical potential of the electrodes 720 based on the position of the substrate with respect to the ion beam, the desired implantation pattern can be attained.

FIG. 9 shows the use of a pulsed extraction power supply 740 that is activated whenever the contact region 170 of the substrate 100 is in a position where the ion beam will irradiate it. The pulse is then deactivated whenever the ion beam exposes the exposed emitter region 160.

Other components of the ion implantation system can be similarly controlled so as to vary the ion beam current. There are numerous components that can be adjusted in the beam line. For example, a focusing lens element can be pulsed periodically to focus and defocus the beam as the substrate is being scanned to create alternating regions of high and low dopant doses. Such focusing elements may be magnetic (i.e. quadrupole lenses) or electrostatic (i.e. Einzel lenses). The defocusing or focusing of the beam changes the amount of beam that is transmitted into the process chamber (and irradiates the substrate), thus varying the effective beam current incident on the workpiece. In such a scenario, it is possible to dope the entire substrate in a single pass implantation. Alternatively, two passes can be used, if desired. Similarly, other beamline components that control the transmission of beam through the implanter may be changed. Such components include Acceleration/Deceleration voltages, Magnet settings, and the like.

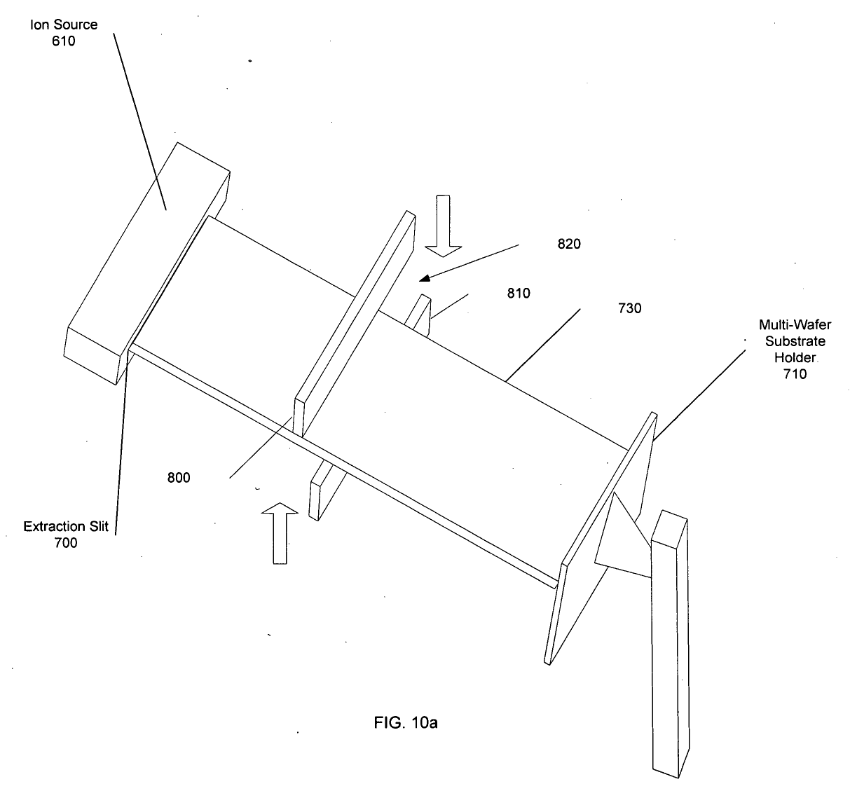

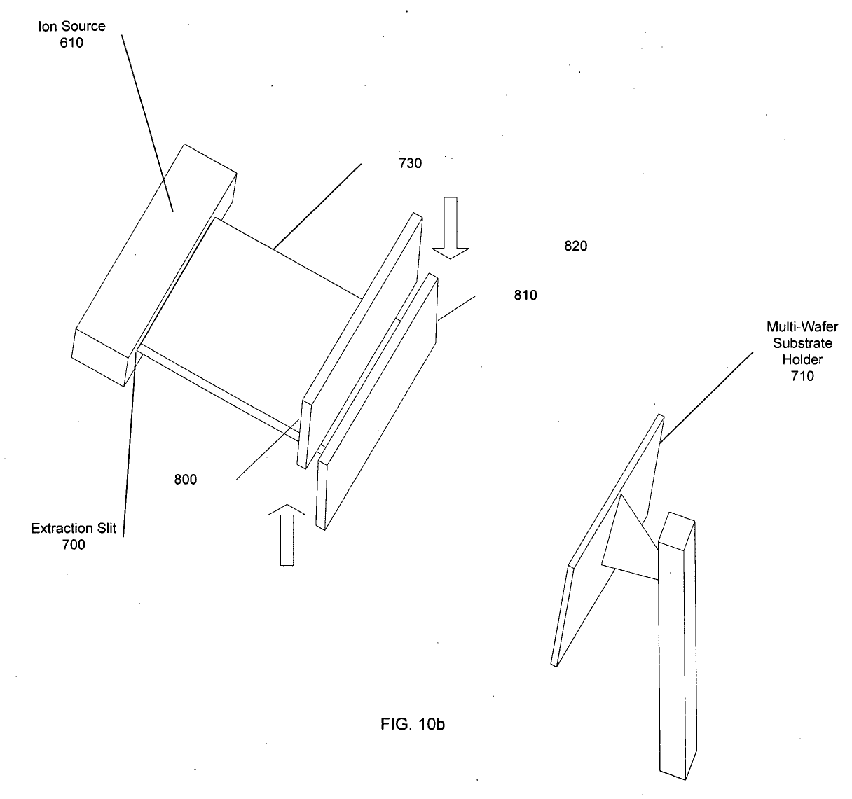

In another embodiment, apertures are used to modify the beam width. In one scenario, two plates 800,810, shown in FIG. 10a, are used to create a variable width aperture 820. In one embodiment, the plates lie on opposite sides of the ion beam 730, and move toward one another to close the aperture 820. When the ion beam is scanning the contact region, the plates 800, 810 are separated, as shown in FIG. 10a, allowing the beam to pass through. When the ion beam is to scan the exposed emitter region 160, the plates 800, 810 move toward one another, so as to minimize or eliminate the aperture 820, as shown in FIG. 10b.

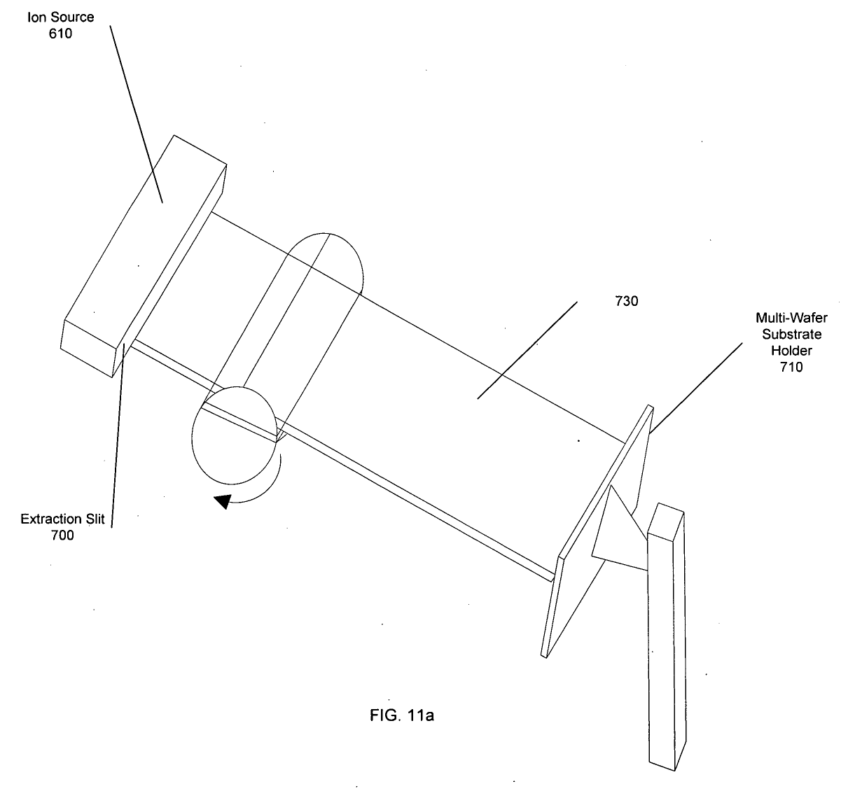

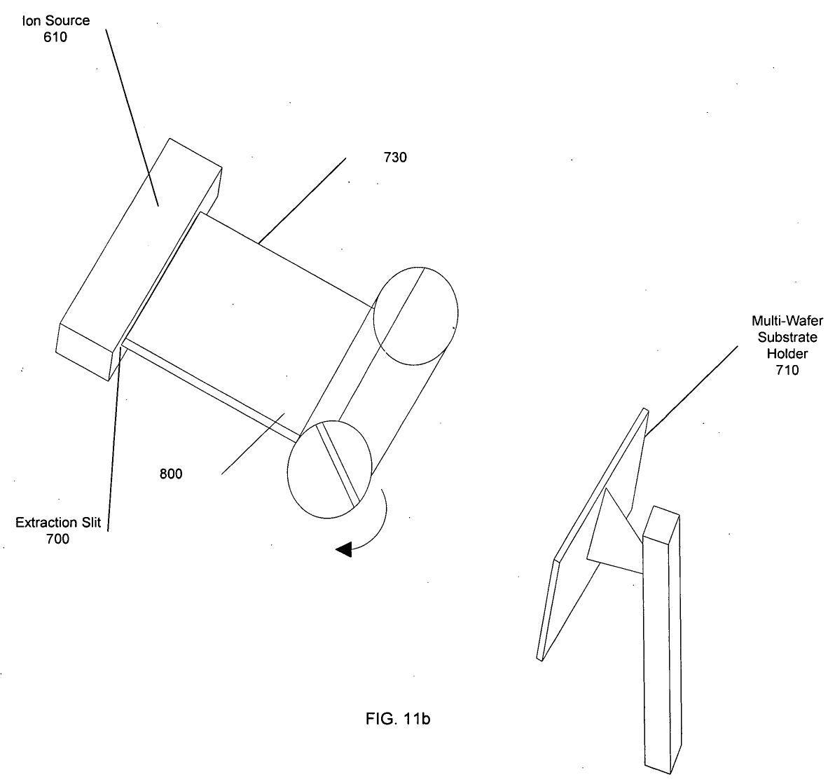

In another scenario, the aperture is used to create the implant pattern. A device, such as that shown in FIGS. 11a and 11b, is used to create the alternating pattern. For example, the device may consist of a rotating barrel or cylinder with a through slit, or aperture, such as along the diameter. The device is rotated about an axis normal to the direction of travel of the ion beam. As this cylinder is rotated about the X axis (axis in which the beam is scanned), the beam can only irradiate the substrate when the slit, or aperture, in the rotating device becomes aligned with the beam direction. FIG. 11a shows the orientation of the aperture when the beam is able to pass through the device. FIG. 11b shows an orientation where the beam is unable to irradiate the substrate. The relative positions of the apertures on the opposing sides of the cylinder, as well as the width of the opposing apertures determine the duty cycle of the implant pattern. For example, wider apertures enable the passage of the beam over a wider range of angular rotation, while narrow apertures permit the passage of the beam over a smaller range of angular rotation. The speed at which the device rotates determines the frequency at which the ion beam irradiates the substrate. While a cylinder is described above, other shaped devices can also be used, as long as the rotation of the device causes the apertures to align such that the ion beam can periodically pass through the device.

To create the desired implantation patterns, it is important for the system to understand the position of the substrate relative to the ion beam. In other words, the system must be aware that the contact region is being exposed in order to supply the proper amount of ions. This information can be determined in a number of ways.

First, the system can rely strictly on timing. In other words, the synchronization of the substrate holder to the other components of the system is accomplished based on the time elapsed since the start of the operation.

A more accurate approach is to include patterns at the edge of the substrate. The system can determine the position of the substrate with respect to the ion beam based on these patterns, and operate accordingly. This method is preferably in that the system does not need any information concerning the implant pattern prior to starting the operation. The patterns on the substrate supply the necessary information for the system to correctly implant the substrate. Such patterns and marking systems are well known to those skilled in the art.

Much of the above description discloses methods of varying the dose or the beam transmission characteristics, based on the vertical position (i.e. Y direction) of the substrate. In other words, the dose can be varied as a function of the substrate location that is being exposed to the ion beam. It is also possible to vary the beam transmission characteristics based on the scan position of the beam (i.e. in the X direction).

Referring to FIG. 6, in certain embodiments, a spot beam is used. In this scenario, the ion beam passes through an electrostatic scanner 660, which deflects the ion beam 650 to produce a scanned beam 655. The scan generator creates a scan voltage waveform, such as a sine, sawtooth or triangle waveform having amplitude and frequency components, which is applied to the scan plates. In most embodiments, the scanning waveform is typically very close to being a triangle wave (constant slope), so as to uniformly expose the scanned beam at every position of the substrate for nearly the same amount of time.

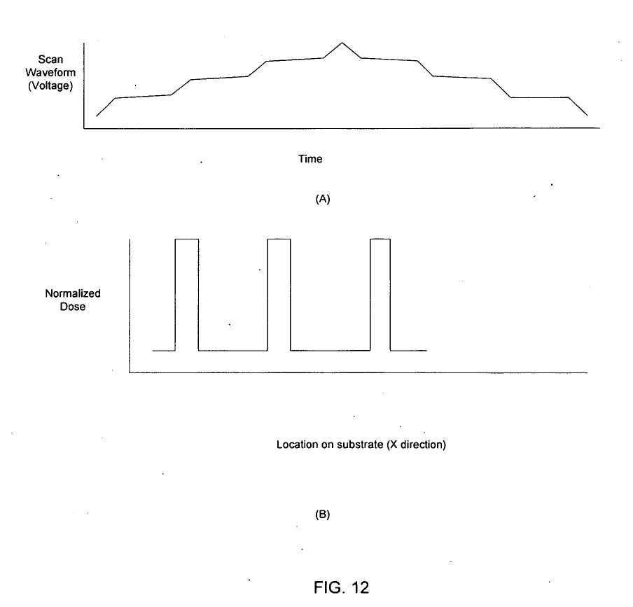

The scanner waveform can be utilized in a variety of ways to vary the dose implanted on the substrate. In one embodiment, the typically triangular waveform is replaced with an alternative waveform. In much the same way that the workpiece can be moved at different rates to vary the dose in the vertical direction (i.e. along the Y axis), modifications to the scan waveform can produce similar effects in the horizontal direction (i.e. along the X axis). FIG. 12a shows a scanning waveform that could be used to generate three areas of high dosing on a substrate in the X direction. The slope of the waveform indicates the speed at which the scanner moves the ion beam across the substrate in the X direction. Those portions of the waveform with very small slopes will create higher doses than those portions with steeper slopes. FIG. 12b shows the resulting substrate dosing, with three areas of high dosing, corresponding to the three portions of the waveform with small slopes, while the remainder of the substrate is lightly dosed.

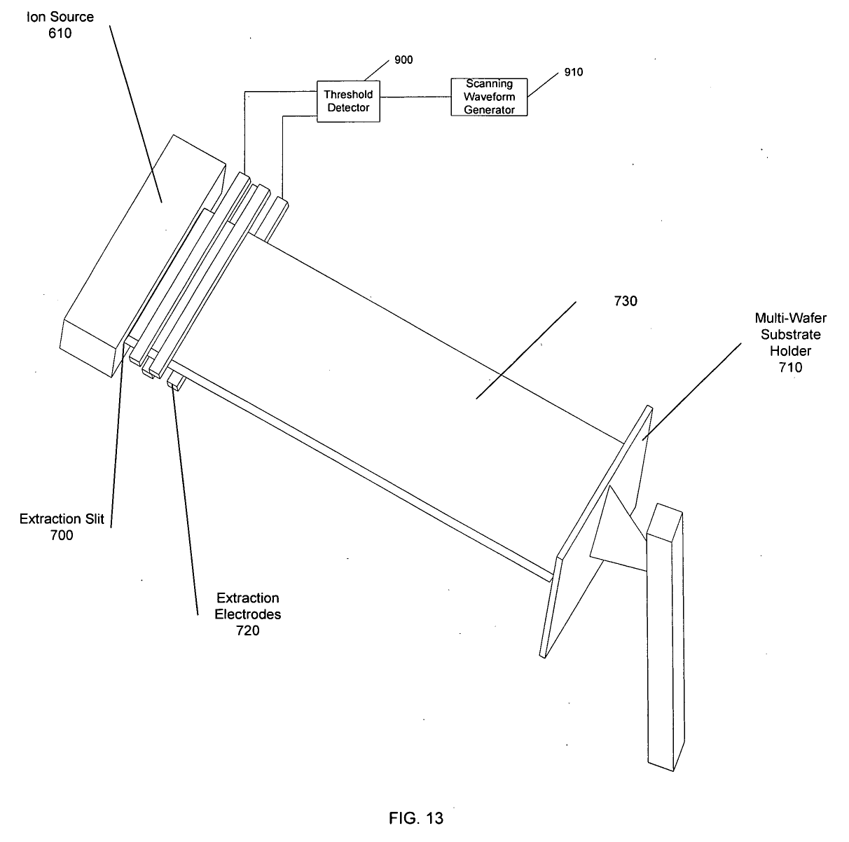

Alternatively, the scanner waveform can be used to vary the adjustable beamline components. In the simplest embodiment, a threshold detector can be used to enable or disable an adjustable beamline component. FIG. 13 shows a threshold detector 900 having one or threshold detection points. The detector receives the scanning waveform from the scanning waveform generator 910 and varies its output such that the adjustable beamline component is enabled when the amplitude of the scanning waveform is between certain values, and is disabled at other times. Such an embodiment can be used to create vertical strips of high dosing on the substrate. By using a plurality of thresholds, it is possible to create patterns similar to that shown in FIG. 12b. For example, assume that the amplitude of the scanning waveform varies between 0 volts and 1 volt. In one embodiment, the threshold detector circuit may enable its output its output if the amplitude of the scanning waveform is between 0.15V and 0.3V, between 0.45V and 0.60V, or between 0.75V and 0.9V. Such a configuration would yield three vertical stripes of higher dosing. Obviously, other embodiments are possible and within the scope of the disclosure.

By combining information about the substrate's position relative to the ion beam with the scanning waveform, more complex patterns can be created on the substrate. In one embodiment, the workpiece support is moved at a constant rate so that time can be used to estimate the position of the substrate relative to the ion beam. A counter or timer is then used, in conjunction with the scanning waveform and the above described threshold detector, to create patterns of dosing which vary as a function of both horizontal and vertical position.

In another embodiment, patterns on the substrate are used to determine the vertical position of the substrate with respect to the ion beam. This information is then used in combination with the scanning waveform to create an output used to control the adjustable beamline component.

What is claimed is:

1. A method of implanting ions into a substrate so as to create a non-uniform dopant dose without a fixed masking layer on said substrate, comprising:
a. Providing an ion implantation system for forming an ion beam having one dimension greater than its second dimension;
b. Exposing a first portion of said substrate to said ion beam;
c. Implanting a first dose of ions in said first portion;
d. Exposing a second portion of said substrate to said ion beam; and
e. Implanting a second dose of ions in said second portion, where said second dose of ions is different than said first dose of ions.

2. The method of claim 1, wherein said substrate comprises a semiconductor material used to make a solar cell.

3. The method of claim 1, wherein said ion implantation system comprises a substrate holder for holding said substrate and moving said substrate relative to said ion beam, said method further comprising:
a. Moving said substrate holder at a first rate when said ion beam is exposed to said first portion of said substrate, and
b. Moving said substrate holder at a second rate when said ion beam is exposed to said second portion of said substrate, wherein said first and second rates are different.

4. The method of claim 1, wherein said ion implantation system comprises a substrate holder for holding said substrate and moving said substrate relative to said ion beam, said method further comprising:
a. Moving said substrate holder at a variable rate between a minimum rate and a maximum rate, such that the minimum rate occurs when said ion beam is exposed to said first portion and said maximum rate occurs when said ion beam is exposed to said second portion.

5. The method of claim 1, wherein said ion implanter system comprises an adjustable beamline component, wherein an adjustment of said component changes the effective beam current incident on said substrate, said method further comprising:
a. Adjusting said component to a first setting when said ion beam is exposed to said first portion of said substrate; and
b. Adjusting said component to a second setting when said ion beam is exposed to said second portion of said substrate.

6. The method of claim 5, wherein said beamline component comprises an element selected from the group consisting of extraction electrodes, focusing lenses, acceleration/deceleration elements and magnets, and said adjustment comprises varying the voltage applied to said element.

7. The method of claim 1, wherein said ion implanter system comprises a scanner for producing a scanned ion beam, and wherein the waveform of said scanned ion beam is controlled by a scanning waveform supplied to said scanner, said method further comprising:
a. Applying a first scanning waveform to said scanner when said ion beam is exposed to said first portion of said substrate; and
b. Applying a second scanning waveform to said scanner when said ion beam is exposed to said second portion of said substrate.

8. The method of claim 1, wherein said ion beam comprises a ribbon beam.

9. The method of claim 1, wherein said ion implantation system comprises an adjustable aperture, adapted to block all or a portion of said ion beam, said method comprising:
a. Adjusting said aperture to a first setting when said ion beam is exposed to said first portion of said substrate; and
b. Adjusting said aperture to a second setting when said ion beam is exposed to said second portion of said substrate.

10. The method of claim 9, wherein said ion implantation system comprises a device adapted to create said adjustable aperture, said method comprising:
a. Providing slits on opposing sides of said device; and
b. Rotating said device about an axis normal to the direction of and in the path of said ion beam, whereby said rotation varies the alignment of said slits and said beam, thereby allowing said beam to pass through said device during portions of said rotation.

11. The method of claim 1, wherein said ion implanter system comprises an adjustable beamline component, wherein an adjustment of said component changes the effective beam current incident on said substrate, and wherein said ion implanter system comprises an electrostatic scanner controlled by a scanning waveform, said method further comprising:
a. Adjusting said component to a first setting when the amplitude of said scanning waveform is at a first level; and
b. Adjusting said component to a second setting when said amplitude of said scanning waveform is at a second level.

12. The method of claim 1, wherein said ion implanter system comprises an electrostatic scanner controlled by a scanning waveform, said method further comprising:
a. Modifying said scanning waveform so as to vary the speed at which said scanner directs ions across said substrate.

13. A method of implanting ions into a substrate, so as to create a non-uniform dopant dose on the implant surface, comprising:
a. Providing an ion implantation system, capable of producing an ion beam having one dimension greater than a second dimension, and comprising a substrate holder to move a substrate relative to said ion beam;
b. Exposing the entire surface of said substrate to a uniform dose of ions by moving said substrate relative to said ion beam until entire wafer has been exposed;
c. Exposing a first portion of said substrate to a second dose of ions;
d. Moving said substrate relative to said ion beam; and
e. Exposing a second portion of said substrate to a third dose of ions.

14. The method of claim 13, wherein said substrate comprises a semiconductor material used to make a solar cell.

15. The method of claim 13, said method further comprising:
a. Moving said substrate holder at a first rate when said ion beam is exposed to said first portion of said substrate, and
b. Moving said substrate holder at a second rate when said ion beam is exposed to said second portion of said substrate, wherein said first and second speeds are different.

16. The method of claim 13, wherein said ion implantation system comprises a substrate holder for holding said substrate and moving said substrate relative to said ion beam, said method further comprising:
a. Moving said substrate holder at a variable rate between a minimum rate and a maximum rate, such that the minimum rate occurs when said ion beam is exposed to said first portion and said maximum rate occurs when said ion beam is exposed to said second portion.

17. The method of claim 13, wherein said ion implanter system comprises an adjustable beamline component, wherein an adjustment of said component changes the effective beam current incident on said substrate, said method further comprising:
a. Adjusting said component to a first setting when said ion beam is exposed to said first portion of said substrate; and
b. Adjusting said component to a second setting when said ion beam is exposed to said second portion of said substrate.

18. The method of claim 17, wherein said beamline component comprises an element selected from the group consisting of extraction electrodes, focusing lenses, acceleration/deceleration elements and magnets, and said adjustment comprises varying the voltage and/or current applied to said element.

19. The method of claim 13, wherein said ion implanter system comprises a scanner for producing a scanned ion beam, and wherein the waveform of said scanned ion beam is controlled by a scanning waveform supplied to said scanner, said method further comprising:
a. Applying a first scanning waveform to said scanner when said ion beam is exposed to said first portion of said substrate; and
b. Applying a second scanning waveform to said scanner when said ion beam is exposed to said second portion of said substrate.

20. The method of claim 13, wherein said ion beam comprises a ribbon beam.

21. The method of claim 13, wherein said ion implantation system comprises an adjustable aperture, adapted to block all or a portion of said ion beam, said method comprising:
a. Adjusting said aperture to a first setting when said ion beam is exposed to said first portion of said substrate; and
b. Adjusting said aperture to a second setting when said ion beam is exposed to said second portion of said substrate.

22. The method of claim 13, wherein said ion implantation system comprises a device adapted to create said adjustable aperture, said method comprising:
a. Providing slits on opposing sides of said device; and
b. Rotating said device about an axis normal to the direction of and in the path of said ion beam, whereby said rotation varies the alignment of said slits and said beam, thereby allowing said beam to pass through said device during portions of said rotation.

23. A method of varying beam transmission in an ion implanter system, wherein said ion implanter system comprises an adjustable beamline component, wherein an adjustment of said component changes the effective beam current incident on said substrate, said method comprising:
a. Adjusting said component to a first setting when said ion beam is exposed to said first portion of said substrate; and
b. Adjusting said component to a second setting when said ion beam is exposed to said second portion of said substrate.

24. The method of claim 23, wherein said ion implanter system comprises a scanner for producing a scanned ion beam, and wherein the waveform of said scanned ion beam is controlled by a scanning waveform supplied to said scanner, wherein said adjustments are based on the amplitude of said scanning waveform.

25. The method of claim 23, wherein said ion implanter system comprises a substrate holder for holding said substrate and moving said substrate relative to said ion beam, wherein said adjustments are based on the position of said substrate relative to said ion beam.
